(19) United States
(12) Patent Application Publication
(10) Pub. No.: US 2026/0082983 A1
(43) Pub. Date: Mar. 19, 2026

(54) SEMICONDUCTOR DEVICE

(71) Applicant: FUJI ELECTRIC CO., LTD., Kawasaki-shi (JP)

(72) Inventors: Yuichiro HINATA, Matsumoto-city (JP); Akira HIRAO, Matsumoto-city (JP); Taisuke FUKUDA, Matsumoto-city (JP); Hiromichi GOHARA, Matsumoto-city (JP)

(73) Assignee: FUJI ELECTRIC CO., LTD., Kawasaki-shi (JP)

(21) Appl. No.: 19/312,233

(22) Filed: Aug. 27, 2025

(30) Foreign Application Priority Data
Sep. 17, 2024 (JP) 2024-160387

(51) Int. Cl. H01L 23/31; H01L 23/00; H01L 23/538

(52) U.S. Cl. CPC H10W 74/124; H10W 70/611; H10W 70/65; H10W 90/401; H10W 90/734

(57) ABSTRACT

A semiconductor device, including: a semiconductor chip including an upper surface electrode and a lower surface electrode; an insulated circuit board having on an upper surface thereof a conductive circuit pattern layer, on which the lower surface electrode is disposed; a wiring board having on a lower surface thereof a wiring pattern layer, which faces the upper surface of the insulated circuit board, and is electrically connected to the upper surface electrode; a conductive spacer disposed between the conductive circuit pattern layer and the wiring pattern layer, and having: a lower bonding surface and an upper bonding surface respectively bonded to the conductive circuit pattern layer and the wiring pattern layer; and an encapsulating member encapsulating the semiconductor chip, the insulated circuit board, the wiring board and the conductive spacer while exposing the upper bonding surface of the conductive spacer and a lower surface of the insulated circuit board.

### CROSS-REFERENCE TO RELATED APPLICATION

This application is based upon and claims the benefit of f priority of the prior Japanese Patent Application No. 2024-160387, filed on Sep. 17, 2024, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a semiconductor module and a cooling module on which the semiconductor module is disposed. The semiconductor module includes an insulated circuit board, which has a plurality of conductive circuit pattern plates formed on its upper surface, and semiconductor chips disposed on the conductive circuit pattern plates. This type of semiconductor module includes terminals that are conductively connected to the conductive circuit pattern plates and extend vertically upward from the conductive circuit pattern plates (see, for example, Japanese Laid-open Patent Publication No. 2021-125545, Japanese Laid-open Patent Publication No. 2011-253862, Japanese Laid-open Patent Publication No. 09-321216, and Japanese Laid-open Patent Publication No. 2022-160270).

### SUMMARY OF THE INVENTION

According to one aspect, there is provided a semiconductor device including: a semiconductor chip including an upper surface electrode and a lower surface electrode; an insulated circuit board that includes a conductive circuit pattern layer on an upper surface surface thereof, the lower electrode of the semiconductor chip being disposed on the conductive circuit pattern layer; a wiring board that includes a wiring pattern layer on a lower surface thereof, the wiring pattern layer being disposed to face the upper surface of the insulated circuit board, and being electrically connected to the upper surface electrode of the semiconductor chip; a conductive spacer that is disposed between the conductive circuit pattern layer and the wiring pattern layer, the conductive spacer having: a lower bonding surface bonded to the conductive circuit pattern layer, and an upper bonding surface bonded to the wiring pattern layer, to thereby conductively connect the conductive circuit pattern layer and the wiring pattern layer; and an encapsulating member that encapsulates the semiconductor chip, the insulated circuit board, the wiring board and the conductive spacer while exposing the upper bonding surface of the conductive spacer and a lower surface of the insulated circuit board.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view of a semiconductor device according to a first embodiment;

FIG. 2 is a cross-sectional view of the semiconductor device according to the first embodiment;

FIG. 3 is a plan view of an insulated circuit board on which semiconductor chips and conductive spacers have been laid out according to the first embodiment;

FIG. 4 is a plan view of a printed circuit board according to the first embodiment;

FIG. 5 is a cross-sectional view of (a main part of) the semiconductor device according to the first embodiment;

FIG. 6 is a flowchart of a method of manufacturing a semiconductor module according to the first embodiment;

FIG. 7 is a cross-sectional view depicting a first setting step in the method of manufacturing the semiconductor module according to the first embodiment;

FIG. 8 is a first cross-sectional view depicting a second setting step in the method of manufacturing the semiconductor module according to the first embodiment;

FIG. 9 is a plan view useful in explaining the second setting step in the method of manufacturing the semiconductor module according to the first embodiment;

FIG. 10 is another plan view useful in explaining the second setting step in the method of manufacturing the semiconductor module according to the first embodiment;

FIG. 11 is a second cross-sectional view depicting the second setting step in the method of manufacturing the semiconductor module according to the first embodiment;

FIG. 12 is a cross-sectional view useful in explaining an encapsulating step in the method of manufacturing the semiconductor module according to the first embodiment;

FIG. 13 is a plan view of a semiconductor device according to a comparative example;

FIG. 14 is a cross-sectional view of the semiconductor device according to the comparative example;

FIG. 15 is a cross-sectional view of (a main part of) the semiconductor device according to the comparative example to which an external connection terminal has been bonded;

FIG. 16 is a cross-sectional view of (a main part of) the semiconductor device to which an external connection terminal has been bonded, according to the first embodiment;

FIG. 17 is a plan view of a printed circuit board according to a second embodiment;

FIG. 18 is a cross-sectional view of (a main part of) a semiconductor device according to the second embodiment;

FIG. 19 is a perspective view of a semiconductor device according to a third embodiment;

FIG. 20 is a cross-sectional view of (a main part) the semiconductor device according to the third embodiment;

FIG. 21 is a cross-sectional view of (a main part of) a semiconductor device according to a fourth embodiment;

FIG. 22 is a plan view of an insulated circuit board on which semiconductor chips and conductive spacers have been laid out according to the fourth embodiment;

FIG. 23 is a cross-sectional view of (a main part of) a semiconductor device according to a fifth embodiment; and

FIG. 24 is a cross-sectional view useful in explaining a second setting step in a method of manufacturing a semiconductor module according to the fifth embodiment.

### DETAILED DESCRIPTION OF THE INVENTION

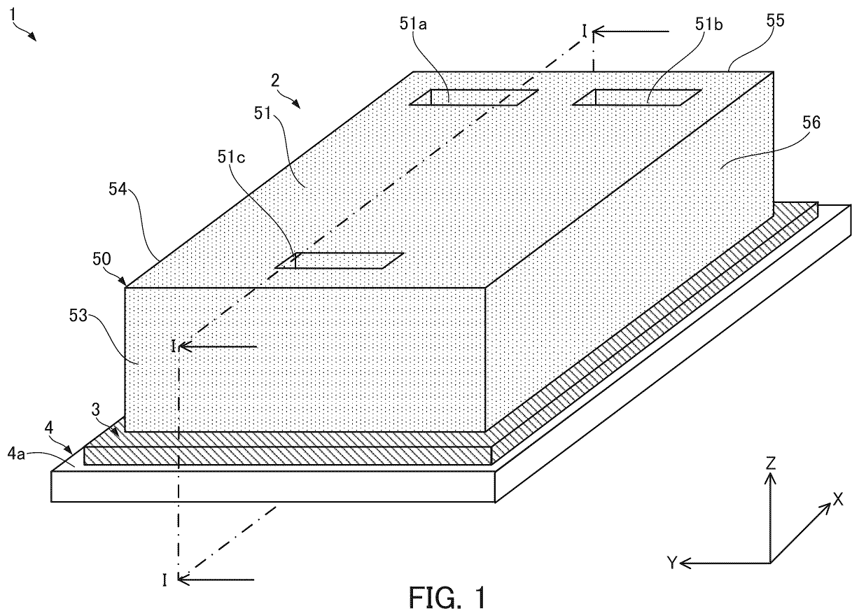

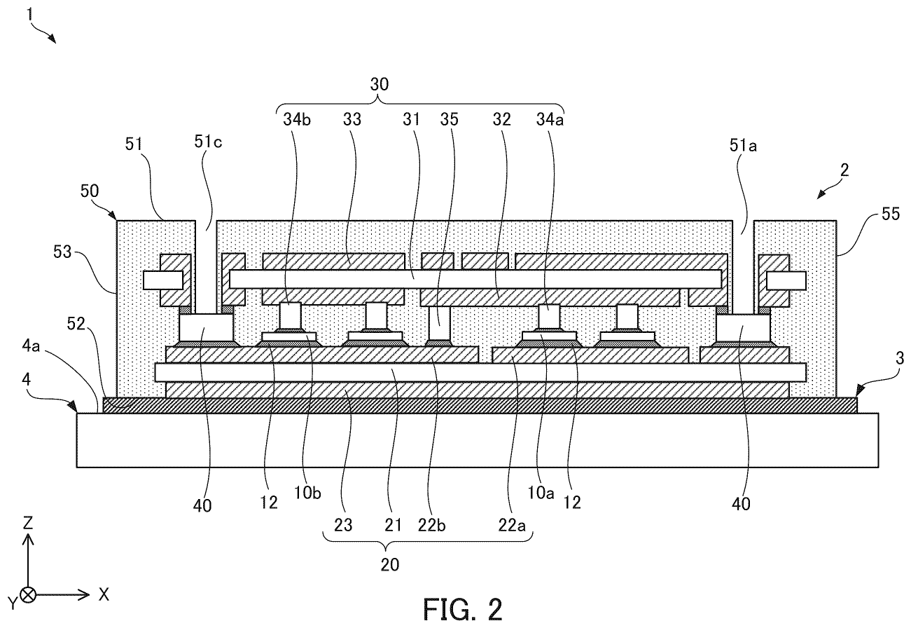

Preferred embodiments will be described below with reference to the accompanying drawings. In the following description, the expressions “front surface” and “upper surface” refer to an X-Y plane that faces upward (the +Z direction) for a semiconductor device 1 in FIGS. 1 and 2. In the same way, the expression “up” refers to an upward direction (the +Z direction) for the semiconductor device 1 in FIGS. 1 and 2. The expressions “rear surface” and “lower surface” refer to an X-Y plane that faces downward (the −Z direction) for the semiconductor device 1 in FIGS. 1 and 2. In the same way, “down” refers to a downward direction (the −Z direction) for the semiconductor device 1 in FIGS. 1 and 2. The same directions are referred to as needed in other drawings. The expressions “front surface”, “upper surface”, “up”, “rear surface”, “lower surface”, “down”, and “side surface” are merely convenient expressions for specifying relative positional relationships and do not limit the technical scope of the present embodiments. For example, the expressions “up” and “down” do not necessarily refer to the vertical direction with respect to the ground. That is, the “up” and “down” directions are not limited to the direction of gravity. In addition, in the following description, the expression “main component” refers to a component that composes 80% or higher by volume. The expression “substantially the same” indicate a range of ±10%. In addition, “perpendicular” and “parallel” may indicate a range of ±10°. Also in the following description, components that are the same have been assigned the same reference numerals, and the description thereof may be omitted or simplified.

### First Embodiment

First, a semiconductor device according to a first embodiment will be described with reference to FIG. 1. FIG. 1 is a perspective view of a semiconductor device according to a first embodiment. The semiconductor device 1 includes a semiconductor module 2 and a cooling module 4 on which the semiconductor module 2 has been disposed via a bonding member 3. Note that the semiconductor device 1 may also include other components as needed.

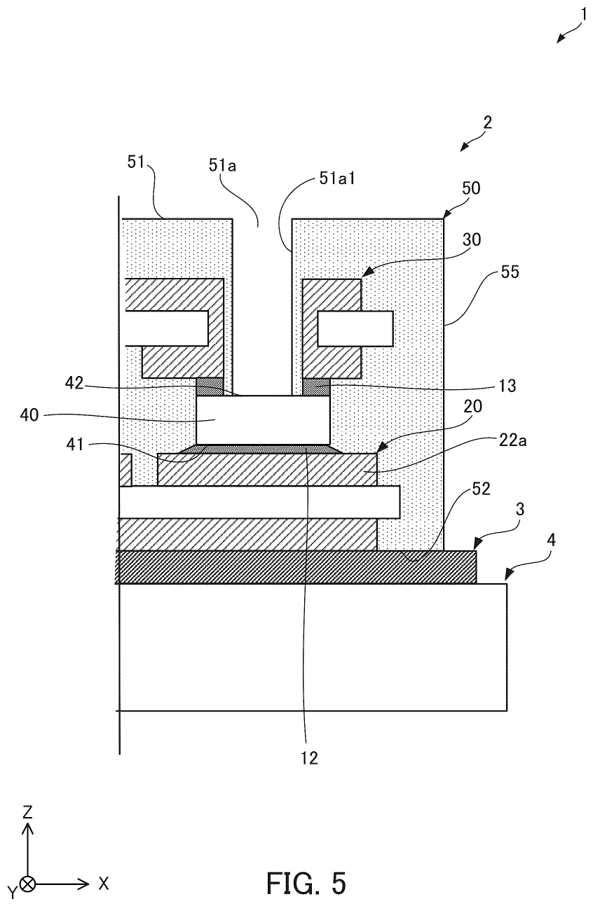

The semiconductor module 2 may be entirely encapsulated by an encapsulating member 50 and molded into a cuboid shape. The encapsulating member 50 is surrounded by an upper surface 51, a lower surface 52 (see FIG. 5), and side surfaces 53, 54, 55, and 56.

The upper surface 51 has a rectangular shape in plan view. The upper surface 51 has long sides along the ±X direction and short sides along the ±Y direction. Openings 51a, 51b, and 51c are formed at three locations in the upper surface 51.

Each of the openings 51a, 51b, and 51c has long sides that extend along the ±Y direction and short sides that extend along the ±X direction. The openings 51a and 51b are provided on the +X direction side of the upper surface 51 and extend along a short side of the upper surface 51. The opening 51c is provided at the center on the −X direction side of the upper surface 51 and extends along a short side of the upper surface 51. The openings 51a, 51b, and 51c will be described in detail later.

The lower surface 52 has the same shape and size as the upper surface 51, and is provided on the opposite side to the upper surface 51. As will be described later, an entire lower surface of a metal plate 23 of an insulated circuit board 20 encapsulated by the encapsulating member 50 is exposed from the lower surface 52, and the lower surface 52 may be flush with the lower surface of the metal plate 23.

The side surfaces 53, 54, 55, and 56 sequentially surround the sides of the upper surface 51 and the lower surface 52 in the clockwise direction. Accordingly, in plan view, the side surfaces 53 and 55 are short sides of the semiconductor module 2 and extend along the ±Y direction and the side surfaces 54 and 56 are long sides of the semiconductor module 2 and extend along the ±X direction.

Parts where the surfaces of the encapsulating member 50 of the semiconductor module 2 join and corner portions may be R-chamfered or C-chamfered. The edges of the openings 51a, 51b, and 51c may also be R-chamfered or C-chamfered.

The cooling module 4 includes, on an upper surface thereof, a placement surface 4a on which the lower surface 52 of the semiconductor module 2 is placed. The placement surface 4a is wider than the lower surface 52, which is the rear surface of the semiconductor module 2, and is substantially flat. The cooling module 4 depicted in FIG. 1 is only schematically illustrated. Specific examples of the cooling module 4 include a heat dissipation base equipped with heat dissipation fins and a cooling device in which a refrigerant circulates. At least part of the cooling module 4 including the placement surface 4a on which the semiconductor module 2 is placed is made of a metal with superior thermal conductivity. Example materials include copper, aluminum, and an alloy containing at least one of these. In this example, copper is included. To improve corrosion resistance, a plating treatment may be performed on the surface of the placement surface 4a of the cooling module 4. The plating material used here contains nickel. Example plating materials include nickel, a nickel-phosphorus alloy, and a nickel-boron alloy.

The bonding member 3 is provided between the lower surface 52 of the semiconductor module 2 and the placement surface 4a of the cooling module 4. That is, the shape and size of the bonding member 3 in plan view in the −Z direction may be substantially the same as or slightly larger than the shape and size of the lower surface 52 of the semiconductor module 2. That is, the bonding member 3 is in contact with the lower surface 52 of the semiconductor module 2 and is in contact with the placement surface 4a of the cooling module 4.

The bonding member 3 is a thermally conductive adhesive and may be made of a material with thermally conductive, electrically insulating, and adhesive properties. The material may be selected so that a predetermined thermal conductivity is obtained. As one example, the bonding member 3 may contain resin as a main component and a filler. As one example, the resin may be epoxy-based resin. Example main components of the filler include ceramics and metal. Ceramics have high thermal conductivity, with examples thereof including silicon oxide, aluminum oxide, boron nitride, and aluminum nitride. When the filler is ceramics, the bonding member 3 containing this filler achieves sufficient thermal conductivity in addition to adhesiveness. Metal has high thermal conductivity and electrical conductivity, with examples thereof including silver, copper, gold, nickel, chromium, aluminum, and alloys containing at least one of these. When the filler is a metal, the bonding member 3 containing this filler achieves sufficient thermal conductivity in addition to adhesiveness, and is also electrically conductive. Since the bonding member 3 is electrically conductive, the metal plate 23 exposed from the lower surface 52 of the semiconductor module 2 and the cooling module 4 are placed at the same electrical potential, which makes it possible to prevent electrical discharge from occurring between the semiconductor module 2 and the cooling module 4. The bonding member 3 is not limited to thermally conductive adhesive, and may be solder or a sintered body. The solder may be any of the example materials indicated for solder 12, described later. As examples, a sintered material that constitutes the sintered body may be powdered silver, iron, copper, aluminum, titanium, nickel, tungsten, or molybdenum. Outer corner portions of the bonding member 3 may be R-chamfered. This prevents the concentration of stress at the corner portions. By doing so, it is possible to suppress peeling of the bonding member 3 from the placement surface 4a.

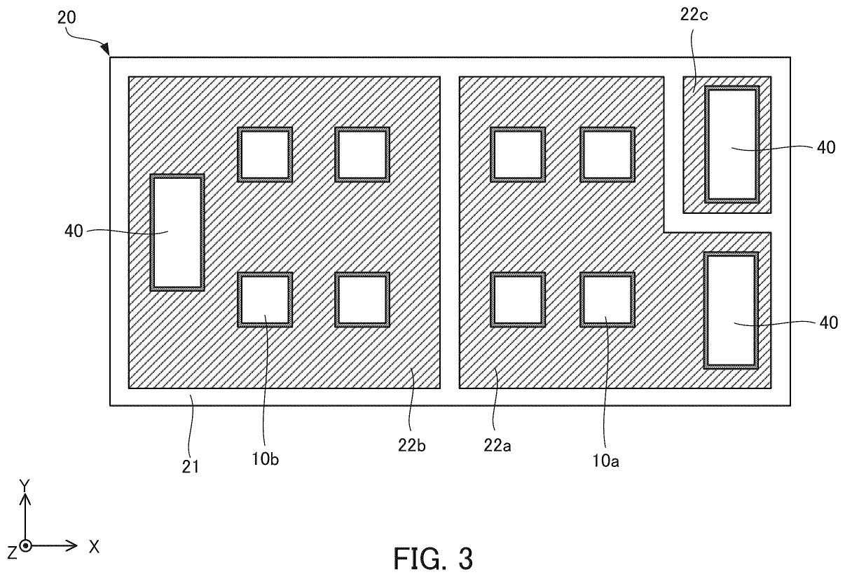

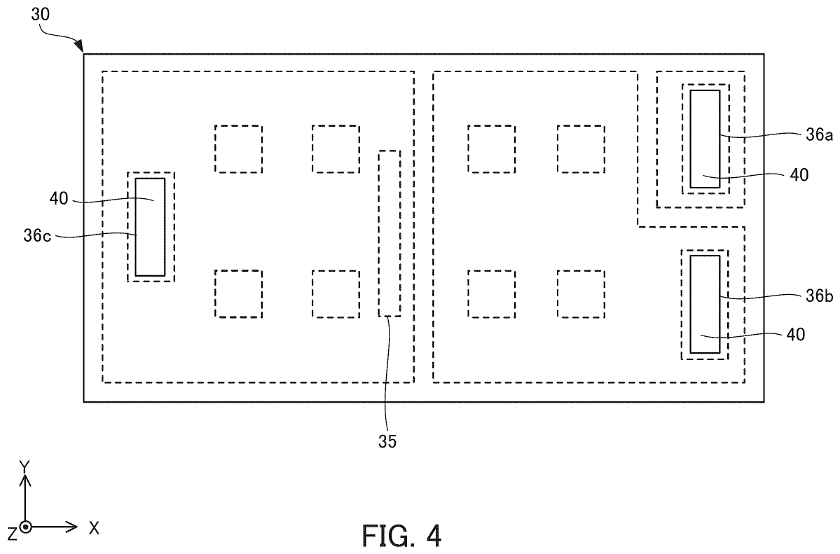

The semiconductor module 2 will now be described in detail with reference to FIGS. 2 to 5 together with FIG. 1. FIG. 2 is a cross-sectional view of the semiconductor device according to the first embodiment. FIG. 3 is a plan view of an insulated circuit board on which semiconductor chips and conductive spacers have been laid out according to the first embodiment. FIG. 4 is a plan view of a printed circuit board according to the first embodiment. FIG. 5 is a cross-sectional view of (a main part of) the semiconductor device according to the first embodiment.

Note that FIG. 2 is a cross-sectional view taken along a plane indicated by a dashed line in FIG. 1 and viewed in the direction of an arrow I. FIG. 3 is a plan view of only the insulated circuit board 20 included in the semiconductor device 1, on which semiconductor chips 10a and 10b and conductive spacers 40 have been laid out. FIG. 4 is a plan view of only a wiring board 30 that is included in the semiconductor device 1 and has been disposed facing the insulated circuit board 20. FIG. 5 is an enlarged view of a conductive spacer 40 and a periphery thereof on the +X direction side in the cross-sectional view in FIG. 2.

The semiconductor module 2 included in the semiconductor device 1 includes the semiconductor chips 10a and 10b, the insulated circuit board 20, the wiring board 30, and the conductive spacers 40. In the semiconductor module 2, such components are encapsulated by the encapsulating member 50.

The semiconductor chips 10a and 10b may be power metal-oxide-semiconductor field-effect transistors (MOSFETs) that have silicon carbide as a main component. In a power MOSFET, the body diode may function as a freewheeling diode (FWD). As one example, each of the semiconductor chips 10a and 10b includes an input electrode (drain electrode), which is a lower surface electrode, on a rear surface, and an output electrode (source electrode) and a control electrode (gate electrode), which are two types of upper surface electrode, on a front surface. Note that the control electrode may be positioned in the center of one edge portion of the front surface of each of the semiconductor chips 10a and 10b, or at a position that is displaced from the center along an edge portion.

Alternatively, the semiconductor chips 10a and 10b may include a switching element that has silicon as a main component. As one example, the switching element is a reverse-conducting insulated gate bipolar transistor (RC-IGBT). The RC-IGBT is a semiconductor element in which an IGBT and an FWD are configured in anti-parallel in a single chip.

Each of the semiconductor chips 10a and 10b includes an input electrode (collector electrode), which is a lower surface electrode, on a rear surface, and an output electrode (emitter electrode) and a control electrode (gate electrode), which are two types of upper surface electrode, on a front surface. As with the case of a power MOSFET, the control electrode may be positioned in the center of one edge portion of the front surface of each of the semiconductor chips 10a and 10b, or at a position that is displaced from the center along an edge portion.

As another example, the semiconductor chips 10a and 10b may be semiconductor chips that have silicon as a main component and each include a pair of a switching element and a diode element. In more detail, semiconductor chips including a switching element and a diode element may be disposed in place of the semiconductor chips 10a, and semiconductor chips including a switching element and a diode element may be disposed in place of the semiconductor chip 10b. For example, the switching element is a power MOSFET or an IGBT. A semiconductor chip including a switching element includes, for example, an input electrode (a drain electrode in a power MOSFET, and a collector electrode in an IGBT) as a lower surface electrode on a rear surface, and a gate electrode as a control electrode which is an upper surface electrode and an output electrode (a source electrode in a power MOSFET, and an emitter electrode in an IGBT) as an upper surface electrode on a front surface. For the diode element, for example, a Schottky barrier diode (SBD) or a P-intrinsic-N (PiN) the FWD. A diode is used as semiconductor chip including a diode element includes an output electrode (cathode electrode) as a main electrode on a rear surface and an input electrode (anode electrode) as a main electrode on a front surface.

The semiconductor chips 10a and 10b may be bonded via the solder 12 to conductive circuit pattern layers 22a and 22b, respectively, described later. The solder 12 is made of a solder component. The solder component referred to here is a substance constituting the solder 12 and includes lead-free solder containing a predetermined alloy as a main component. Here, the predetermined alloy contains tin. Example alloys include at least one of a tin-silver alloy, a tin-silver-copper alloy, a tin-zinc-bismuth alloy, a tin-copper alloy, a tin-silver-indium-bismuth alloy, and a tin-antimony alloy. The solder component may include additives. Example additives include nickel, germanium, cobalt, and silicon. Accordingly, examples of the solder component include tin and at least one of silver, zinc, copper, bismuth, indium, and antimony. The solder component may further include at least one of nickel, germanium, cobalt, and silicon, for example. A sintered body may be used instead of the solder 12. In the case of using a sintered body for the bonding, the sintered material is, for example, powdered silver, iron, copper, aluminum, titanium, nickel, tungsten, or molybdenum.

The insulated circuit board 20 includes an insulating layer 21, conductive circuit pattern layers 22a, 22b, and 22c, and the metal plate 23. The insulating layer 21 and the metal plate 23 are rectangular in shape in plan view. Corner portions of the insulating layer 21 and the metal plate 23 may be R-chamfered or C-chamfered. The size of the metal plate 23 is smaller than the size of the insulating layer 21 in plan view, and the metal plate 23 is formed inside the insulating layer 21.

Examples of the insulating layer 21 include a ceramic substrate. The ceramic substrate is made of ceramics with high thermal conductivity. Example ceramics include a material containing aluminum oxide, aluminum nitride, or silicon nitride as a main component. The insulating layer 21 is rectangular in shape in plan view. Examples of the insulated circuit board 20 including the insulating layer 21 with the above configuration include a direct copper bonding (DCB) substrate and an active metal brazed (AMB) substrate.

The insulating layer 21 may alternatively be made of resin. The resin may be a material with properties including low thermal resistance and high electrical insulation. An example of such a resin includes thermosetting resin. The thermosetting resin may also contain a filler. The thermal resistance of the insulating layer 21 may be further reduced by controlling the material and amount of the filler contained in the insulating layer 21.

Examples of thermosetting resin include at least one of epoxy resin, cyanate resin, polyimide resin, benzoxazine resin, unsaturated polyester resin, phenol resin, melamine resin, silicone resin, and maleimide resin. The filler is made of at least one of an oxide and a nitride. Examples of the oxide include silicon oxide and aluminum oxide. Examples of the nitride include silicon nitride, aluminum nitride, and boron nitride. Hexagonal boron nitride may also be used as the filler.

The thickness of the insulating layer 21 depends on the rated voltage of the semiconductor module 2. That is, the higher the rated voltage of the semiconductor module 2, the greater the thickness of the insulating layer 21. On the other hand, it is also important to make the insulating layer 21 as thin as possible to reduce thermal resistance.

The conductive circuit pattern layers 22a, 22b, and 22c are made of metal with superior thermal conductivity. Example materials include copper, aluminum, and an alloy containing at least one of these. In this example, copper is included. To improve corrosion resistance, the surfaces of the conductive circuit pattern layers 22a, 22b, and 22c may be plated. The plating material in this case contains nickel. Example plating materials include nickel, a nickel-phosphorus alloy, and a nickel-boron alloy. When the bonding member 3 is a sintered body containing silver, the plating material may contain silver.

The conductive circuit pattern layers 22a, 22b, and 22c are formed over the entire surface of the insulating layer 21 except for edge portions. In plan view, it is preferable for end portions of the conductive circuit pattern layers 22a, 22b, and 22c that face the outer periphery of the insulating layer 21 to overlap end portions in the outer periphery of the metal plate 23. With this configuration of the insulated circuit board 20, stress is balanced with the metal plate 23 on the rear surface of the insulating layer 21. By doing so, damage, such as excessive warping and cracking of the insulating layer 21 is further suppressed. Note that the illustrated conductive circuit pattern layers 22a, 22b, and 22c are mere examples. The number, shapes, and sizes of the conductive circuit pattern layers formed on the insulating layer 21 may be selected to realize a desired circuit.

As depicted in FIG. 3, the conductive circuit pattern layers 22a, 22b, and 22c are formed on the upper surface of the insulating layer 21. That is, the conductive circuit pattern layer 22a is provided on the +X direction side of the insulating layer 21, is L shaped, and includes a rectangular cutout in the +X direction and the +Y direction. The conductive circuit pattern layer 22b is provided adjacent to the conductive circuit pattern layer 22a on the −X direction side of the insulating layer 21, and is rectangular in shape in plan view. The conductive circuit pattern layer 22c is formed in the cutout region of the conductive circuit pattern layer 22a on the insulating layer 21.

The semiconductor chips 10a and a conductive spacer 40 are bonded via the solder 12 to the conductive circuit pattern layer 22a. The conductive spacer 40 is provided at the +X direction end of the conductive circuit pattern layer 22a. The semiconductor chips 10a are provided in the center of the conductive circuit pattern layer 22a. The semiconductor chips 10b and a conductive spacer 40 are bonded via the solder 12 to the conductive circuit pattern layer 22b. The conductive spacer 40 is provided at the −X direction end of the conductive circuit pattern layer 22b. The semiconductor chips 10b are provided in the center of the conductive circuit pattern layer 22b. A conductive spacer 40 is provided via the solder 12 on the conductive circuit pattern layer 22c. The conductive spacers 40 will be described in detail later.

The metal plate 23 is made of metal with superior thermal conductivity. Example materials include copper, aluminum, and an alloy containing at least one of these. In this example, copper is included. To improve corrosion resistance, the surface of the metal plate 23 may be plated. The plating material used in this case includes nickel. Example plating materials include nickel, a nickel-phosphorus alloy, and a nickel-boron alloy.

The wiring board 30 is a printed circuit board, for example. The wiring board 30 includes an insulating board 31, a lower wiring pattern layer 32 formed on a lower surface of the insulating board 31, and an upper wiring pattern layer 33 formed on an upper surface of the insulating board 31. The wiring board 30 further includes connection members 34a and 34b, which extend downward, and a connection wiring member 35. As described later, the connection members 34a and 34b may be electrically connected to the output electrodes that are upper surface electrodes of the semiconductor chips 10a and 10b. Also, although not depicted, the wiring board 30 includes members connection that are electrically connected to the control electrodes that are upper surface electrodes of the semiconductor chips 10a and 10b. The wiring board 30 is disposed so that the lower wiring pattern layer 32 faces the upper surface of the insulated circuit board 20.

The insulating board 31 is shaped as a flat plate and is made of an insulating material. As this material, a material obtained by impregnating a substrate with resin is used. As examples, the substrate has paper, glass cloth, or glass nonwoven fabric as a main component. Example resins include phenol resin, epoxy resin, and polyimide resin. Specific examples of the insulating board include a paper phenol substrate, a paper epoxy substrate, a glass epoxy substrate, a glass polyimide substrate, and a glass composite substrate. The insulating board is also rectangular in shape in plan view. Corner portions of the insulating board may be R-chamfered or C-chamfered.

The lower wiring pattern layer 32 and the upper wiring pattern layer 33 have predetermined pattern predetermined circuit for shapes to construct a realizing a power conversion function. The lower wiring pattern layer 32 and the upper wiring pattern layer 33 are made of a material with superior electrical conductivity. Example materials include copper, aluminum, nickel, silver, and an alloy containing at least one of these. The surfaces of the lower wiring pattern layer 32 and the upper wiring pattern layer 33 may be plated to improve corrosion resistance. Example materials used in the plating treatment include nickel, a nickel-phosphorus alloy, and a nickel-boron alloy. Alternatively, a solder resist may be applied instead of plating.

The connection members 34a and 34b are electrically connected as appropriate to the lower wiring pattern layer 32 and the upper wiring pattern layer 33, respectively, and are further bonded via solder 13 the upper surface electrodes of the semiconductor chips 10a and 10b. Note that in this case, the upper surface electrodes may be output electrodes. Although not depicted, the wiring board 30 further includes connection members that are bonded via the solder 13 to the control electrodes that are upper surface electrodes of the semiconductor chips 10a and 10b.

As one example, in plan view, the connection wiring member 35 may be plate-shaped and rectangular in shape where the long sides extend along the ±Y direction and the short sides extends along the ±X direction. The connection wiring member 35 is electrically connected to the lower wiring pattern layer 32 and is bonded via the solder 13 to the conductive circuit pattern layer 22b of the insulated circuit board 20.

The connection members 34a and 34b and the connection wiring member 35 are made of a material with superior electrical conductivity. Example materials include copper, aluminum, nickel, silver, and an alloy containing at least one of these. The surfaces of the connection members 34a and 34b and the connection wiring member 35 may be plated to improve corrosion resistance. Example materials used in the plating treatment include nickel, a nickel-phosphorus alloy, and a nickel-boron alloy.

On the wiring board 30, through-hole portions 36a, 36b, and 36c are formed at positions that face the conductive spacers 40 in plan view. The through-hole portions 36a, 36b, and 36c pass through the wiring board 30 in the ±Z direction. The shape of the through-hole portions 36a, 36b, and 36c in plan view may be the same of upper bonding surfaces 42 of the as the shape conductive spacers 40, described later. However, the openings of the through-hole portions 36a, 36b, and 36c are smaller in area than the upper bonding surfaces 42 of the conductive spacers 40. As one example, as depicted in FIG. 4, the upper bonding surfaces 42 of the conductive spacers 40 are exposed from the through-hole portions 36a, 36b, and 36c of the wiring board 30. Note that inner surfaces of the through-hole portions 36a, 36b, and 36c of the wiring board 30 may be plated.

As one example, each conductive spacer 40 has a block (cuboid) shape, and includes a lower bonding surface 41 on a lower surface and the upper bonding surface 42 on the upper surface. The conductive spacers 40 are made of a material with superior electrical conductivity. Example materials include copper, aluminum, nickel, silver, and an alloy containing at least one of these. The surfaces of the conductive spacers 40 may be plated to improve corrosion resistance. Examples of the material used in the plating treatment include nickel, a nickel-phosphorus alloy, and a nickel-boron alloy.

The conductive spacers 40 are disposed between the insulated circuit board 20 and the wiring board 30. As one example, as depicted in FIG. 2, a conductive spacer 40 is disposed between the conductive circuit pattern layer 22b of the insulated circuit board 20 and the lower wiring pattern layer 32 of the wiring board 30. A conductive spacer 40 is also disposed between the conductive circuit pattern layer 22a of the insulated circuit board 20 and the lower wiring pattern layer 32 of the wiring board 30.

Here, the lower bonding surfaces 41 of the conductive spacers 40 are bonded via the solder 12 to the conductive circuit pattern layers 22a and 22b of the insulated circuit board 20. The upper bonding surfaces 42 of the conductive spacers 40 are bonded via the solder 13 to the lower wiring pattern layer 32 of the wiring board 30. FIG. 5 depicts a configuration where a conductive spacer 40 is disposed between the conductive circuit pattern layer 22a of the insulated circuit board 20 and the lower wiring pattern layer 32 of the wiring board 30.

Note that the solder 13 may be disposed in a continuous annular shape in the outer edge regions of the upper bonding surfaces 42 of the conductive spacers 40. This means that the upper bonding surfaces 42 of the conductive spacers 40 are bonded via the solder 13 to opening edge portions of the through-hole portions 36a, 36b, and 36c of the lower wiring pattern layer 32 of the wiring board 30. As a result, the conductive spacers 40 electrically connect the conductive circuit pattern layers 22a and 22b of the insulated circuit board 20 and the lower wiring pattern layer 32 of the wiring board 30.

In this way, the conductive spacers 40 are laid out on the lower wiring pattern layer 32 side of the wiring board 30 relative to the through-hole portions 36a, 36b, and 36c of the wiring board 30. By doing so, the upper bonding surfaces 42 of the conductive spacers 40 form bottom surfaces of the through-hole portions 36a, 36b, and 36c of the wiring board 30 and are exposed from the through-hole portions 36a, 36b, and 36c.

In addition, the inner surfaces of the through-hole portions 36a, 36b, and 36c of the wiring board 30 are encapsulated by the encapsulating member 50 and the openings 51a, 51b, and 51c are formed in the encapsulating member 50. This means that the upper bonding surfaces 42 of the conductive spacers 40 are exposed from the openings 51a, 51b, and 51c in the encapsulating member 50. Note that the encapsulating member 50 also encapsulates the opening 51a, 51b, and 51c-sides of the solder 13 together with the inner surfaces of the through-hole portions 36a, 36b, and 36c of the wiring board 30. Note that FIG. 5 depicts the opening 51a, where an opening inner surface 51a1 of the opening 51a covers an inner surface of the through-hole portion 36a. Although the openings 51b and 51c are not depicted, inner surfaces of openings 51b and 51c cover the inner surfaces of the through-hole portions 36b and 36c.

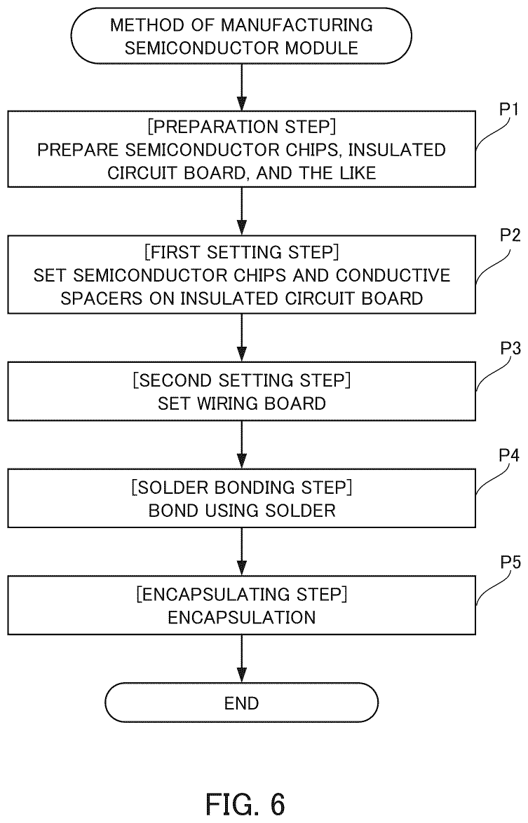

Next, a method of manufacturing the semiconductor module 2 will be described with reference to FIG. 6. FIG. 6 is a flowchart of a method of manufacturing the semiconductor module according to the first embodiment. First, a preparation step of preparing components of the semiconductor module 2 is performed (step P1). As examples of these components, the semiconductor chips 10a and 10b, the insulated circuit board 20, the wiring board 30, the conductive spacers 40, an encapsulating material, and solder are prepared. Other components needed to manufacture the semiconductor module 2 are also prepared. In addition, a manufacturing apparatus and a manufacturing jig needed to manufacture the semiconductor module 2 may be prepared.

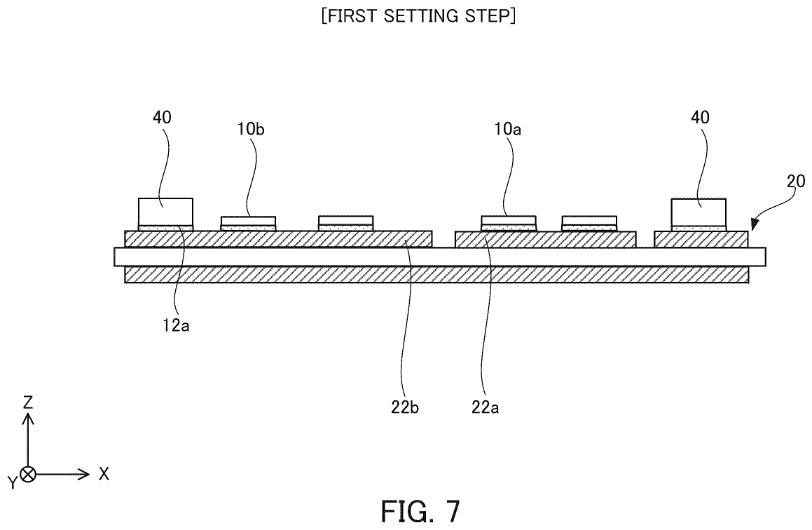

Next, a first setting step of setting the semiconductor chips 10a and 10b and the conductive spacers 40 on the insulated circuit board 20 is performed (step P2). The first setting step will be described with reference to FIG. 7. FIG. 7 is a cross-sectional view depicting the first setting step in the method of manufacturing the semiconductor module according to the first embodiment. FIG. 7 corresponds to the cross-sectional view in FIG. 2.

First, the semiconductor chips 10a and 10b are set via solder 12a on the conductive circuit pattern layers 22a and 22b, respectively, of the insulated circuit board 20. In addition, the conductive spacers 40 are set via the solder 12a on the conductive circuit pattern layers 22a and 22b of the insulated circuit board 20. When doing so, the solder 12a may be set at positions where the connection wiring member 35 of the wiring board 30, described later, is set. The solder 12a used here may be cream solder, for example.

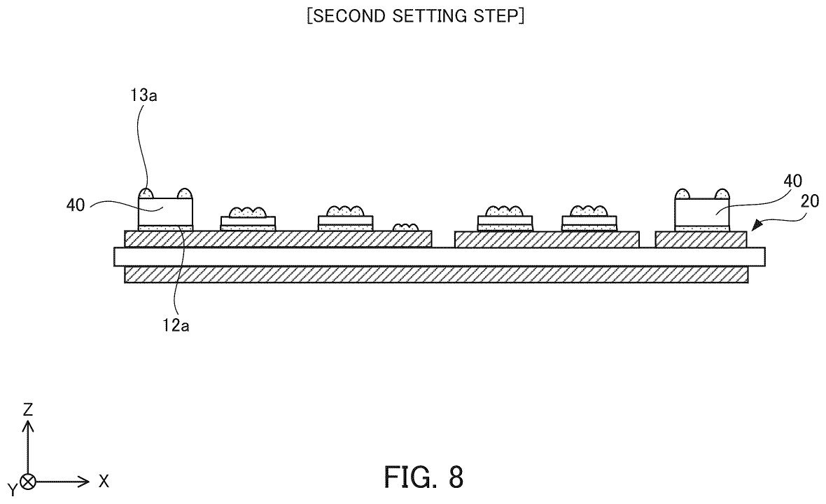

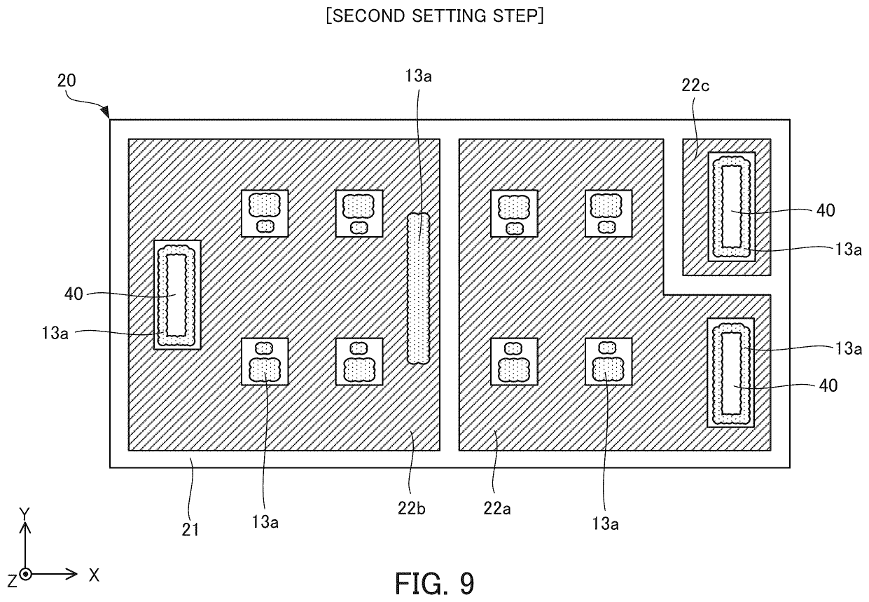

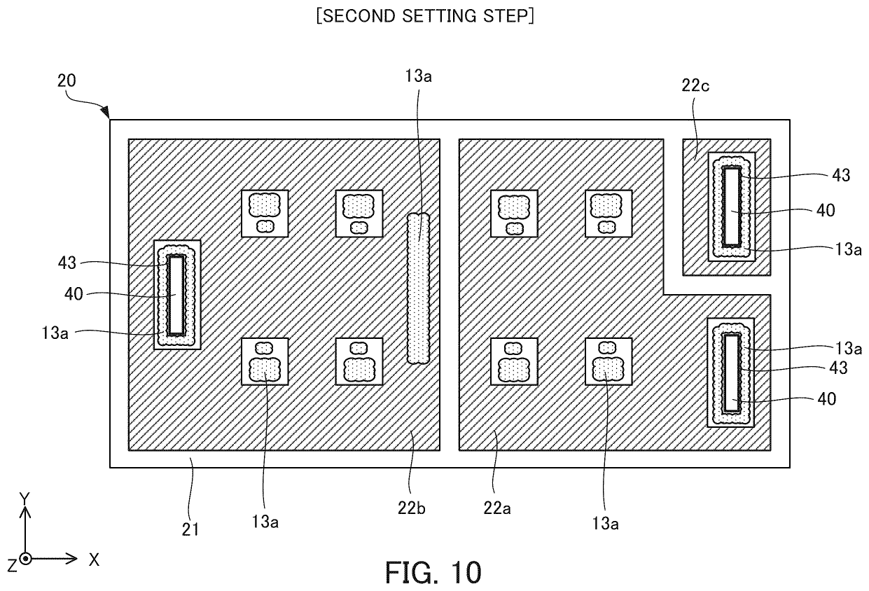

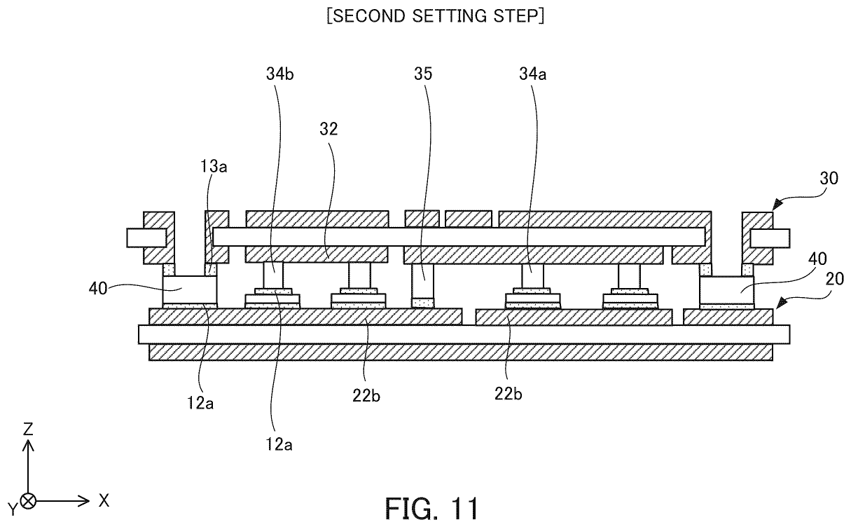

Next, after the step P2, a second setting step of setting the wiring board 30 on the insulated circuit board 20 is performed (step P3). This second setting step will be described with reference to FIGS. 8 to 11. FIG. 8 is a first cross-sectional view depicting a second setting step in the method of manufacturing the semiconductor module according to the first embodiment. FIG. 9 is a plan view useful in explaining the second setting step in the method of manufacturing the semiconductor module according to the first embodiment. FIG. 10 is another plan view useful in explaining the second setting step in the method of manufacturing the semiconductor module according to the first embodiment. FIG. 11 is a second cross-sectional view depicting the second setting step in the method of manufacturing the semiconductor module according to the first embodiment. Similar to FIG. 7, FIGS. 8 and 11 correspond to the cross-sectional view in FIG. 2. FIG. 9 is a plan view of the state in FIG. 8. FIG. 10 is also a plan view similar to FIG. 9.

After step P2, as depicted in FIGS. 8 and 9, solder 13a is set on the upper surface electrodes (output electrodes and control electrodes) of the semiconductor chips 10a and 10b disposed on the insulated circuit board 20. The solder 13a is provided along the outer edge regions of the upper bonding surfaces 42 of the conductive spacers 40. The solder 13a is also set in the region of the conductive circuit pattern layer 22b of the insulated circuit board 20 where the connection wiring member 35 will be placed. The solder 13a may be cream solder, for example. When cream solder is used, the solder 13a is continuously applied in annular shapes along the outer edge regions of the upper bonding surfaces 42 of the conductive spacers 40.

The upper bonding surfaces 42 of the conductive spacers 40 may have solder-repelling portions 43 formed inside the annular applied regions of the solder 13a before the solder 13a is applied. FIG. 10 depicts a case where the solder 13a has been applied to the upper bonding surfaces 42 of the conductive spacers 40 on which the solder-repelling portions 43 have been formed. The solder-repelling portions 43 may be members that repel solder, or may be processed to become solder-repellent. Examples of solder-repellent members include carbon and a resist material. Alternatively, the solder-repelling portions 43 may be blasted as the processing that produces solder repellency. By forming the solder-repelling portions 43 continuously in annular shapes along the insides of the regions where the solder 13a will be applied onto the upper bonding surfaces 42 of the conductive spacers 40, it is possible to suppress wetting and spreading of the solder 13a from the solder-repelling portions 43 to the insides of the upper bonding surfaces 42.

The wiring board 30 is set on the insulated circuit board 20. That is, as depicted in FIG. 11, the connection members 34a and 34b of the wiring board 30 are mounted via the solder 12a on the upper surface electrodes of the semiconductor chips 10a and 10b, respectively. The lower wiring pattern layer 32 of the wiring board 30 is mounted via the solder 13a on the upper bonding surfaces 42 of the conductive spacers 40. The connection wiring member 35 of the wiring board 30 is mounted via the solder 13a on the conductive circuit pattern layer 22b of the insulated circuit board 20.

Next, a solder bonding step of bonding with solder is performed (step P4). After step P3, reflowing of the solder is performed to melt the solder 12a and 13a and the molten solder 12a and 13a is then allowed to harden. By doing so, the semiconductor chips 10a and 10b and the conductive spacers 40 are bonded to the insulated circuit board 20 by the solder 12 obtained by the hardening of the molten solder 12a. The connection members 34a and 34b of the wiring board 30 are also bonded to the upper surface electrodes of the semiconductor chips 10a and 10b via the solder 13 obtained by the hardening of the melted solder 13a. The lower wiring pattern layer 32 of the wiring board 30 is bonded to the upper bonding surface 42 of the conductive spacer 40 via the solder 13 obtained by the hardening of the molten solder 13a. The connection wiring member 35 of the wiring board 30 is bonded to the conductive circuit pattern layer 22a of the insulated circuit board 20 via the solder 13.

Note that as depicted in FIG. 10, when a solder-repelling portion 43 is formed on the upper bonding surface 42 of each conductive spacer 40, the solder 13a melted in the solder bonding step does not enter a region inside the solder-repelling portion 43 on the upper bonding surface 42.

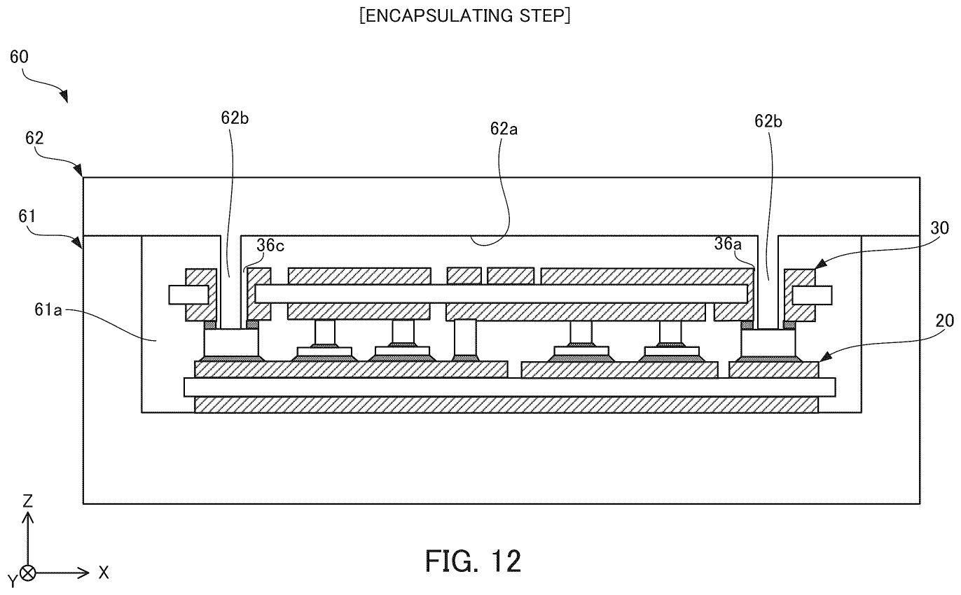

Next, an encapsulating step of encapsulating with an encapsulating member is performed (step P5). The encapsulating step will be described with reference to FIG. 12. FIG. 12 is a cross-sectional view useful in explaining an encapsulating step in the method of manufacturing the semiconductor module according to the first embodiment. FIG. 12 corresponds to the cross-sectional view in FIG. 2.

First, an encapsulating mold 60 used in step P5 includes a lower mold 61 and an upper mold 62. The lower mold 61 is box-shaped and internally includes a housing region 61a. The upper mold 62 is shaped as a flat plate and has a top surface 62a. Three rod-shaped opening molding portions (only two opening molding portions 62b are depicted in FIG. 12) are formed on this top surface 62a. The opening molding portions 62b are formed at positions facing the through-hole portions 36a, 36b, and 36c of the wiring board 30 in plan view. The opening molding portions 62b are formed in shapes capable of penetrating the through-hole portions 36a, 36b, and 36c. When the opening molding portions 62b have penetrated the through-hole portions 36a, 36b, and 36c, gaps are provided with respect to the inner surfaces of the through-hole portions 36a, 36b, and 36c. When this upper mold 62 is attached to an upper portion of the lower mold 61, the housing region 61a becomes enclosed.

In step P5, first, the insulated circuit board 20 to which the semiconductor chips 10a and 10b and the wiring board 30 have been bonded is set in the housing region 61a of the lower mold 61. When doing so, gaps of a certain size or larger are formed (in the ±X direction and the ±Y direction) between the insulated circuit board 20 to which the semiconductor chips 10a and 10b and the wiring board 30 have been bonded and the inner surface of the lower mold 61.

The top surface 62a of the upper mold 62 is disposed on the lower mold 61. When doing so, a certain gap is formed (in the ±Z direction) between the top surface 62a of the upper mold 62 and the upper surface of the wiring board 30. Also at this time, the opening molding portions 62b of the upper mold 62 are inserted into each of the through-hole portions 36a, 36b, and 36c of the wiring board 30. As one example, as depicted in FIG. 12, the opening molding portions 62b of the upper mold 62 are inserted into the through-hole portions 36a and 36c of the wiring board 30 and come into contact with the upper bonding surfaces 42 of the conductive spacers 40. In this state, gaps are present between the opening molding portions 62b of the upper mold 62 and the through-hole portions 36a and 36c of the wiring board 30. A gap is also formed between the top surface 62a of the upper mold 62 and the wiring board 30.

In this manner, the insulated circuit board 20 to which the semiconductor chips 10a and 10b and the wiring board 30 have been bonded is set in the housing region 61a of the encapsulating mold 60. The housing region 61a is then filled with an encapsulating material to encapsulate the insulated circuit board 20, to which the semiconductor chips 10a and 10b and the wiring board 30 have been bonded, in the housing region 61a. The encapsulating material hardens to form the encapsulating member 50, thereby molding the semiconductor module 2 inside the encapsulating mold 60. By removing the lower mold 61 and the upper mold 62 of the encapsulating mold 60, the semiconductor module 2 included in the semiconductor device 1 depicted in FIGS. 1 and 2 is obtained.

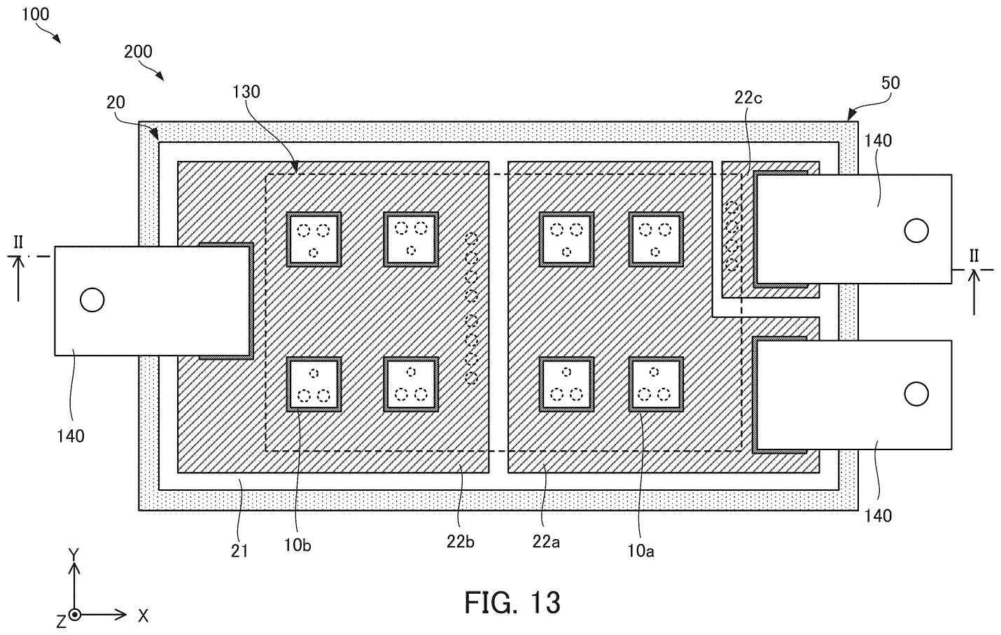

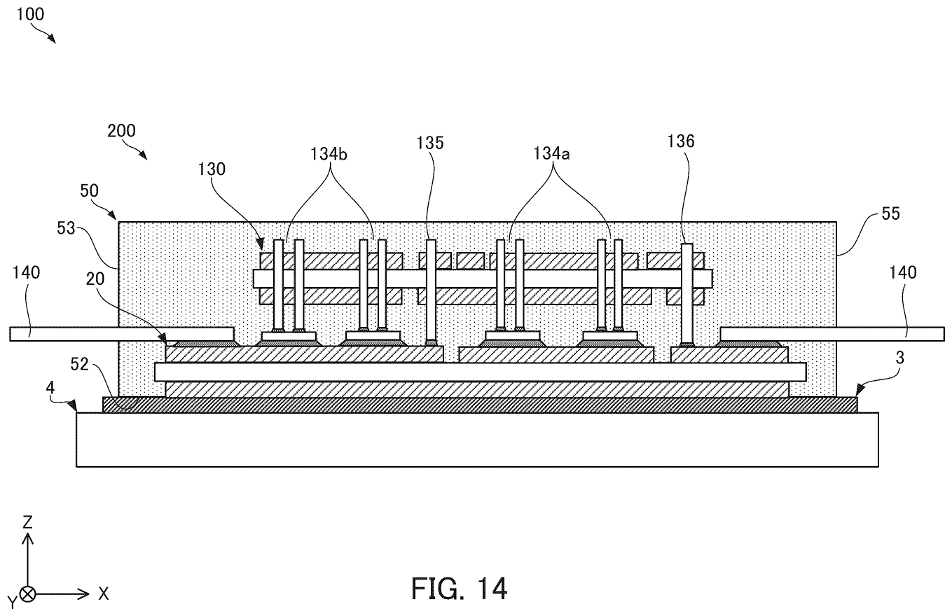

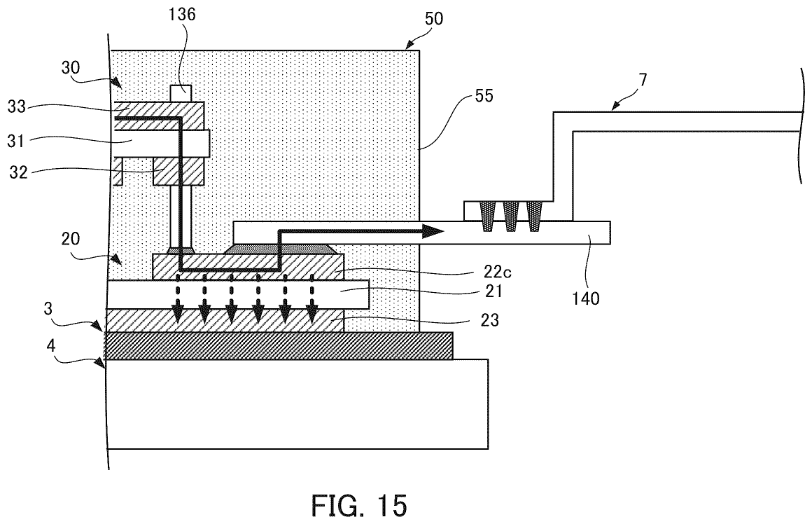

Here, a semiconductor device according to a comparative example will be described with reference to FIGS. 13 to 15. FIG. 13 is a plan view of a semiconductor device according to a comparative example. FIG. 14 is a cross-sectional view of the semiconductor device according to the comparative example. FIG. 15 is a cross-sectional view of (a main part of) the semiconductor device according to the comparative example to which an external connection terminal has been bonded.

Note that FIG. 13 is a plan view of a semiconductor device 100 in FIG. 14, and depicts a state where an upper portion of an encapsulating member 50 has been removed. In FIG. 13, the position of a wiring board 130 and the positions of implant pins connected to semiconductor chips 10a and 10b are indicated by dashed lines. FIG. 14 is a cross-sectional view taken along a chain line II-II in FIG. 13. FIG. 15 is an enlarged view of the +X direction side of FIG. 14, and depicts a case where a bus bar 7 (external connection terminal) has been bonded to a main terminal 140. In the configuration included in a semiconductor module 200 included in the semiconductor device 100 according to this comparative example, components that are the same as those included in the semiconductor module 2 according to the first embodiment have been assigned the same reference numerals.

The semiconductor device 100 according to this comparative example includes the semiconductor module 200 and a cooling module 4 on which the semiconductor module 200 is disposed via a bonding member 3. The semiconductor module 200 may be entirely encapsulated by the encapsulating member 50 and molded into a cuboid shape. However, openings 51a, 51b, and 51c are not formed in the encapsulating member 50 of this comparative example.

The semiconductor module 200 included in the semiconductor device 100 includes the semiconductor chips 10a and 10b, an insulated circuit board 20, the wiring board 130, and main terminals 140. In the semiconductor module 200, these components are encapsulated by the encapsulating member 50.

The insulated circuit board 20 is provided with the main terminals 140 in place of the conductive spacers 40 of the first embodiment. Each of the main terminals 140 extends to the outside (in the ±X direction) of the insulated circuit board 20. Accordingly, one main terminal 140 extends outward from a side surface 53 of the encapsulating member 50 and two main terminals 140 extend outward from a side surface 55 in parallel with an upper surface 51 of the encapsulating member 50.

The wiring board 130 includes an insulating board 31, a lower wiring pattern layer 32 formed on the lower surface of the insulating board 31, and an upper wiring pattern layer 33 formed on the upper surface of the insulating board 31. The wiring board 130 also includes implant 134a and 134b, which extend downward, and a connection wiring pin 135. As will be described later, the implant pins 134a and 134b may be electrically connected to output electrodes that are upper surface electrodes of the semiconductor chips 10a and 10b. Also, although not depicted, the wiring board 130 also includes implant pins that are electrically connected to control electrodes that are upper surface electrodes of the semiconductor chips 10a and 10b. The wiring board 130 is disposed so that the lower wiring pattern layer 32 faces the upper surface of the insulated circuit board 20. The implant pins 134a and 134b and the connection wiring pin 135 may all be formed in pin shapes, may be connected to the same components as the connection members 34a and 34b and the connection wiring member 35 in the first embodiment, and may perform the same functions.

The semiconductor module 200 included in the semiconductor device 100 may be connected to an external device via an external connection terminal. As one example, the semiconductor module 200 may be electrically connected to a capacitor, which is an external device, to function as a power conversion system. As depicted in FIG. 15, this connection may be achieved by the bus bar 7 included in the capacitor being bonded by laser welding to the main terminal 140 of the semiconductor module 200.

As one example, current flows from the semiconductor module 200 to the capacitor along a solid arrow indicated in FIG. 15. When this happens, a large current exceeding several hundred amperes flows through the bus bar 7. Although performance-dependent, the guaranteed temperature of the capacitor is about 100° C., creating a need to reduce the temperature caused by the application of a large current. Here, the temperature is lowered by radiating heat downward from a conductive circuit pattern layer 22c as indicated by the dashed line arrows in FIG. 15. To increase heat dissipation, it is effective to increase the length (area) of the conductive circuit pattern layer 22c. As a result of this, the main terminal 140 becomes elongated, and the wiring path is also elongated.

However, elongation of the wiring path leads to an increase in the size of the semiconductor module 200 and further increases the inductance. A surge voltage may be generated due to this inductance. When this surge voltage exceeds the breakdown withstand voltage of the semiconductor chips 10a and 10b, the semiconductor chips 10a and 10b will be damaged, causing a malfunction of the semiconductor module 200.

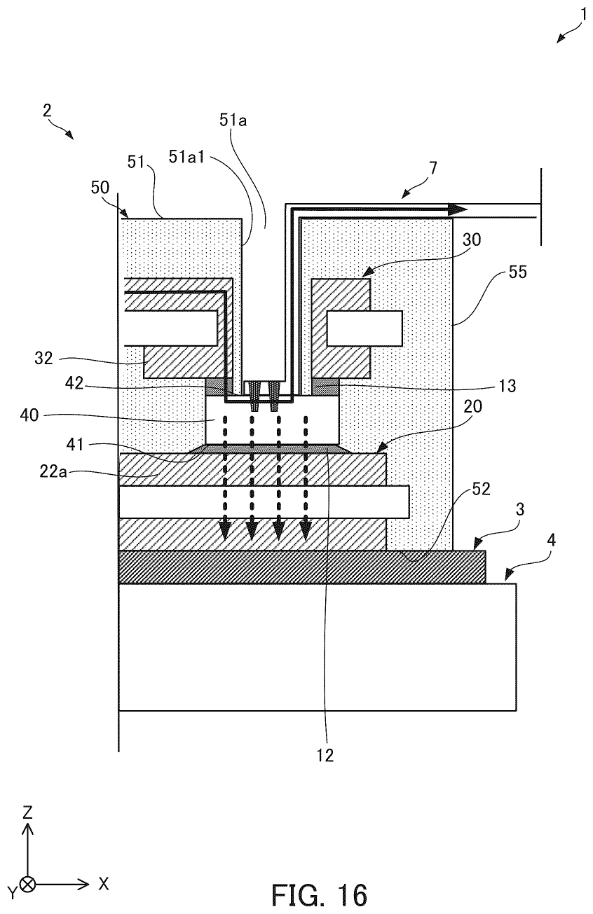

Next, the bonding of a bus bar 7 to the semiconductor module 2 included in the semiconductor device 1 will be described with reference to FIG. 16. FIG. 16 is a cross-sectional view of (a main part of) the semiconductor device to which an external connection terminal has been bonded, according to the first embodiment. Note that FIG. 16 depicts a case where the bus bar 7 is provided in the opening 51a of the semiconductor module 2 depicted in FIG. 5. As depicted in FIGS. 15 and 16, the bus bar 7 may be formed in an appropriate shape for the location being connected. The bus bar 7 may be included in a capacitor, for example.

Also in the first embodiment, similarly to the comparative example described above, the semiconductor module 2 included in the semiconductor device 1 may be connected to an external device via an external connection terminal. In such configuration also, the semiconductor module 2 may function as a power conversion system by being electrically connected via the bus bar 7 to a capacitor, which is an external device. In this first embodiment, the front end portion of the bus bar 7 is placed in contact with the upper bonding surface 42 of the conductive spacer 40 through the opening 51a of the semiconductor module 2, and is bonded by laser welding, for example.

The semiconductor module 2 of the first embodiment does not include the main terminals 140 of the comparative example, and current flows into the conductive spacer 40 via the wiring board 30 along the solid arrow in FIG. 16. This makes it possible to make the semiconductor module 2 smaller than the semiconductor module 200 of the comparative example.

Since the semiconductor module 2 is miniaturized, the current path from the wiring board 30 to the bus bar 7 is also shorter than the current path from the wiring board 30 to the bus bar 7 of the semiconductor module 200 of the comparative example. This suppresses the occurrence of inductance in the semiconductor module 2 and reduces the occurrence of failures in the semiconductor module 2. The conductive spacer 40 will generate heat due to the current passing from the wiring board 30 to the conductive spacer 40. The heat generated here is radiated downward from the conductive spacer 40 via the conductive circuit pattern layer 22c, as indicated by the dashed line arrows in FIG. 16. This means that increases in temperature of the bus bar 7 are suppressed, so that the occurrence of failures at a capacitor including the bus bar 7 is reduced.

The semiconductor module 2 included in the semiconductor device 1 described above includes: the semiconductor chips 10a and 10b equipped with the upper surface electrodes and the lower surface electrodes; the insulated circuit board 20 that has the conductive circuit pattern layers 22a, 22b, and 22c on the upper surface with the lower surface electrodes of the semiconductor chips 10a and 10b disposed on the conductive circuit pattern layers 22a and 22b; the wiring board 30 that has the lower wiring pattern layer 32 on the lower surface, where the lower wiring pattern layer 32 is disposed to face the upper surface of the insulated circuit board 20 and the lower wiring pattern layer 32 is electrically connected to the upper surface electrodes of the semiconductor chips 10a and 10b; the conductive spacers 40 that are disposed between the conductive circuit pattern layers 22a, 22b, and 22c and the lower wiring pattern layer 32, have the lower bonding surfaces 41 bonded to the conductive circuit pattern layers 22a and 22b and the upper bonding surfaces 42 bonded to the lower wiring pattern layer 32, and conductively connect the conductive circuit pattern layers 22a and 22b to the lower wiring pattern layer 32; and the encapsulating member 50 that encapsulates the semiconductor chips 10a and 10b, the insulated circuit board 20, the wiring board 30, and the conductive spacer 40 while exposing the upper bonding surfaces 42 of the conductive spacers 40 and the lower surface of the insulated circuit board 20. With this semiconductor module 2, it is possible to supply current to the outside in the ±Z direction using the conductive spacer(s) 40 provided between the insulated circuit board 20 and the wiring board 30. This enables the semiconductor module 2 to be miniaturized. This also means that it is possible to shorten the current path from the wiring board 30 to the bus bar 7, which suppresses the occurrence of inductance and reduces the occurrence of failure in the semiconductor module 2. Even when heat is generated at the conductive spacer 40 due to current passing from the wiring board 30 to the conductive spacer 40, such heat is radiated downward from the conductive spacer 40 via the conductive circuit pattern layer 22c. This suppresses an increase in the temperature of the bus bar 7.

### Second Embodiment

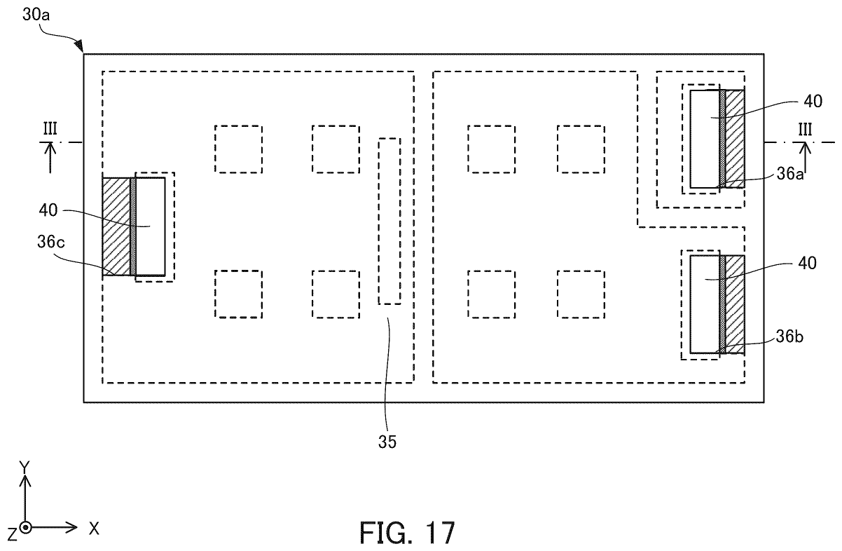

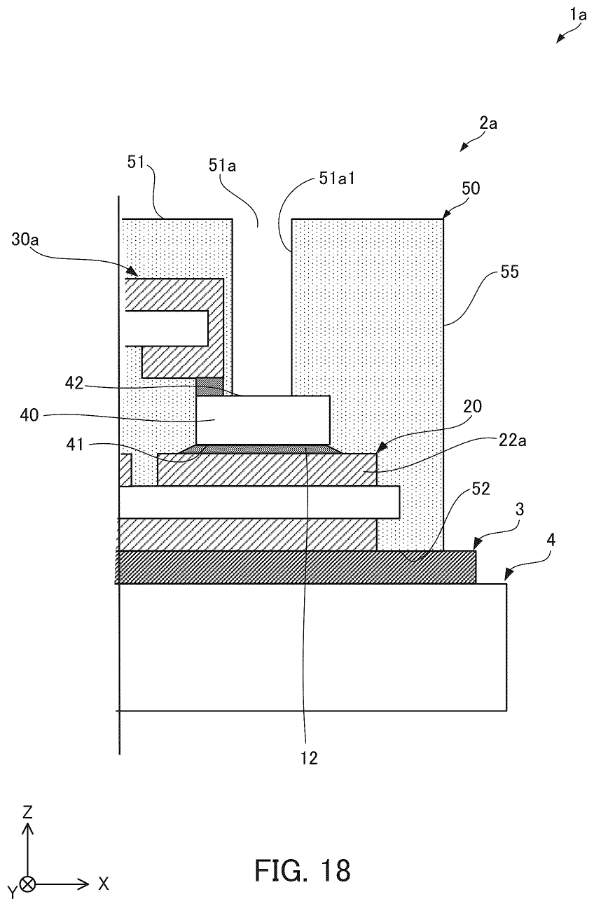

A semiconductor module 2a included in a semiconductor device 1a according to a second embodiment will now be described with reference to FIGS. 17 and 18. FIG. 17 is a plan view of a printed circuit board according to the second embodiment. FIG. 18 is a cross-sectional view of (a main part of) the semiconductor device according to the second embodiment. Note that the description here will mainly focus on differences from the semiconductor module 2 of the first embodiment.

The semiconductor device 1a according to the second embodiment includes the semiconductor module 2a and a cooling module 4 on which the semiconductor module 2a is disposed via a bonding member 3. The semiconductor module 2a includes semiconductor chips 10a and 10b, an insulated circuit board 20, a wiring board 30a, conductive spacers 40, and encapsulating member 50 that encapsulates these components.

However, compared to the wiring board 30 of the first embodiment, the wiring board 30a in this second embodiment has cut outs which include through-hole portions 36a, 36b, and 36c formed from end portions on both sides in the ±X direction. Accordingly, the opening edge portions of the through-hole portions 36a, 36b, and 36c, which are the cut outs formed in the wiring board 30a of the second embodiment, are formed in U-shapes.

In this case, on the conductive spacers 40, which are attached to the through-hole portions 36a, 36b, and 36c of the wiring board 30a from the lower surface side of the wiring board 30a, the solder 13 may be provided on the upper bonding surfaces 42 along the three sides of the U-shaped opening edge portions of the through-hole portions 36a, 36b, and 36c.

The encapsulating member 50 encapsulates the semiconductor chips 10a and 10b, the insulated circuit board 20, the wiring board 30a, and the conductive spacers 40. Openings 51a, 51b, and 51c, which correspond to the conductive spacers 40, are formed in the encapsulating member 50 in the same way as in the first embodiment.

Since it is possible to form the through-hole portions 36a, 36b, and 36c of the wiring board 30a according to the second embodiment through a simple cut out process performed on end portions in the ±X direction of the wiring board 30a, formation of the through-holes portions is simplified. This suppresses the manufacturing cost of the wiring board 30a. Note that on the wiring board 30a of the second embodiment also, the inner surfaces of the through-hole portions 36a, 36b, and 36c may be plated.

### Third Embodiment

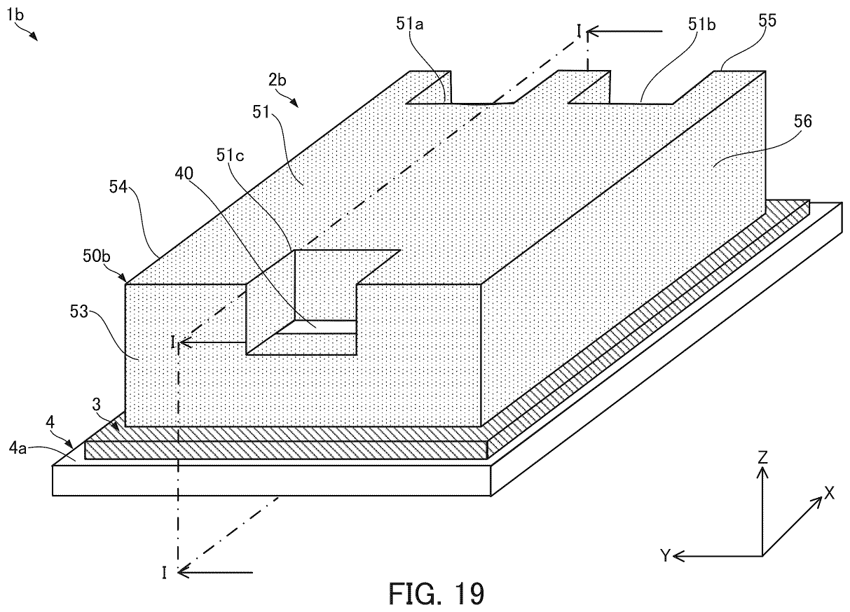

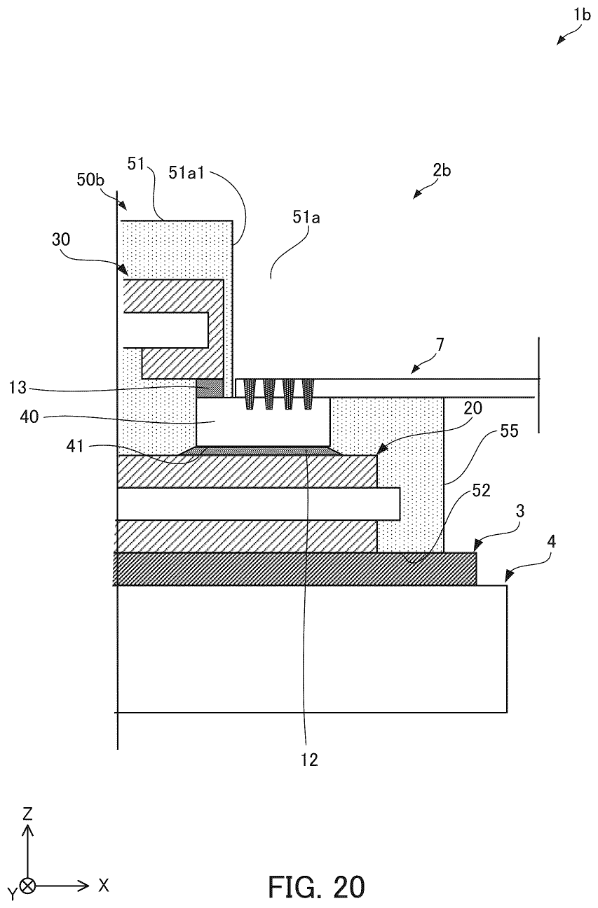

A semiconductor module 2b included in a semiconductor device 1b according to a third embodiment will now be described with reference to FIGS. 19 and 20. FIG. 19 is a perspective view of the semiconductor device according to the third embodiment. FIG. 20 is a cross-sectional view of (a main part) the semiconductor device according to the third embodiment. Here, changes from the semiconductor module 2a of the second embodiment will be mainly described.

The semiconductor device 1b according to the third embodiment also includes a semiconductor module 2b and a cooling module 4 on which the semiconductor module 2b is disposed via a bonding member 3. The semiconductor module 2b includes semiconductor chips 10a and 10b, an insulated circuit board 20, a wiring board 30a, conductive spacers 40, and an encapsulating member 50b that encapsulates these components.

In this third embodiment, as depicted in FIG. 19, openings 51a, 51b, and 51c of the encapsulating member 50b are formed by a cut out process on end portions in the ±X direction. Here, it is sufficient for only upper bonding surfaces 42 of the conductive spacers 40 to be exposed from the bottom surfaces of the openings 51a, 51b, and 51c of the encapsulating member 50b.

As depicted in FIG. 20, a bus bar 7 is attached to the semiconductor module 2b including the encapsulating member 50b. That is, inside the openings 51a, 51b, and 51c (the opening 51a is depicted in FIG. 20) of the encapsulating member 50b, the bus bar 7 may be attached to an upper bonding surface 42 of the conductive spacer 40 so as to be parallel to an upper surface 51 of the encapsulating member 50b. This makes it easy to attach the bus bars 7 to the openings 51a, 51b, and 51c of the semiconductor module 2b.

### Fourth Embodiment

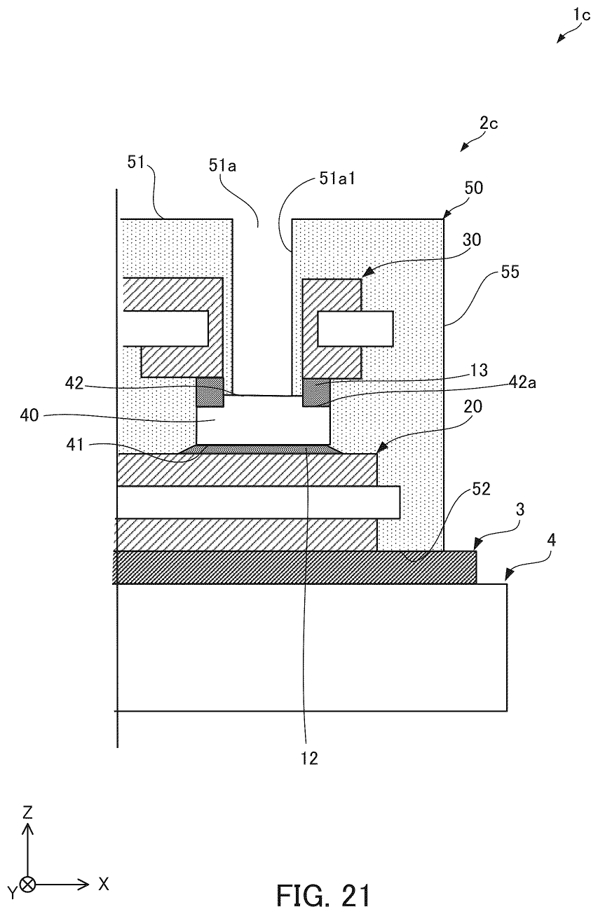

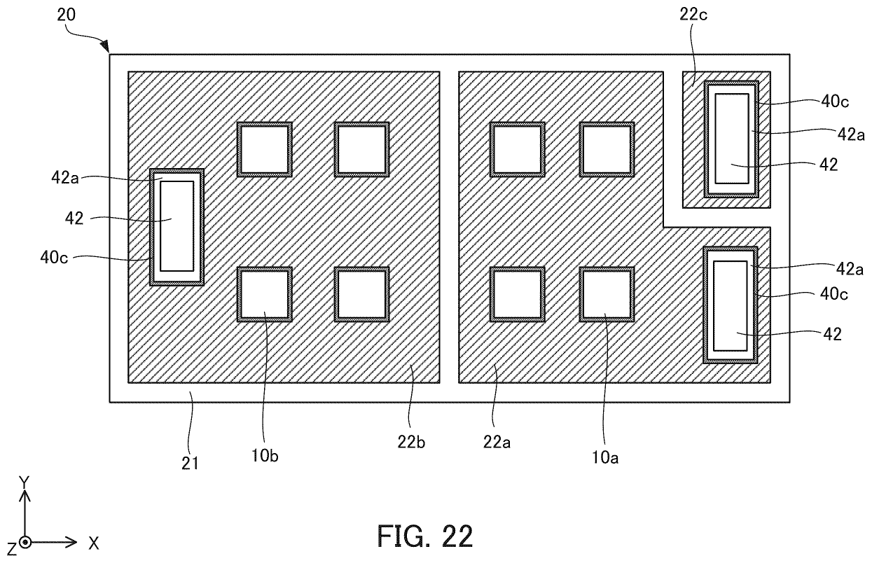

A semiconductor module 2c included in a semiconductor device 1c according to the fourth embodiment will now be described with reference to FIGS. 21 and 22. FIG. 21 is a cross-sectional view of (a main part of) the semiconductor device according to the fourth embodiment. FIG. 22 is a plan view of an insulated circuit board on which semiconductor chips and conductive spacers have been laid out according to the fourth embodiment. Note that the description here will mainly focus on differences from the semiconductor module 2 of the first embodiment.

The semiconductor device 1c according to the fourth embodiment includes the semiconductor module 2c and a cooling module 4 on which the semiconductor module 2c is disposed via a bonding member 3. The semiconductor module 2c includes semiconductor chips 10a and 10b, an insulated circuit board 20, a wiring board 30, conductive spacers 40c, and an encapsulating member 50 that encapsulates these components.

In this fourth embodiment, regions of upper bonding surfaces 42 of the conductive spacers 40c that face the opening edge portions of through-hole portions 36a, 36b, and 36c of the wiring board 30 are lower than (that is, recessed from) the upper bonding surface 42. That is, a continuous and annular step 42a is formed in an outer edge region of the upper bonding surface 42 of each conductive spacer 40c.

This makes it possible for solder 13 that bonds the upper bonding surface 42 of each conductive spacer 40c and the wiring board 30 to be thicker than in the configuration used in the comparative example. When temperature changes, such as repeated generation of heat and cooling, occur for the semiconductor module 2c, the increased thickness of the solder 13 reduces the occurrence of distortion in the solder 13. As a result, deterioration in the product life of the semiconductor module 2 is suppressed, and the reliability of the semiconductor module 2 is improved.

Although it is most preferable to form the step 42a formed in the conductive spacer 40c in the entire outer edge region of the upper bonding surface 42, it is effective to form the step 42a in at least part of the outer edge region. It is more preferable to form the step 42a on a pair of opposing long sides of the upper bonding surface 42.

### Fifth Embodiment

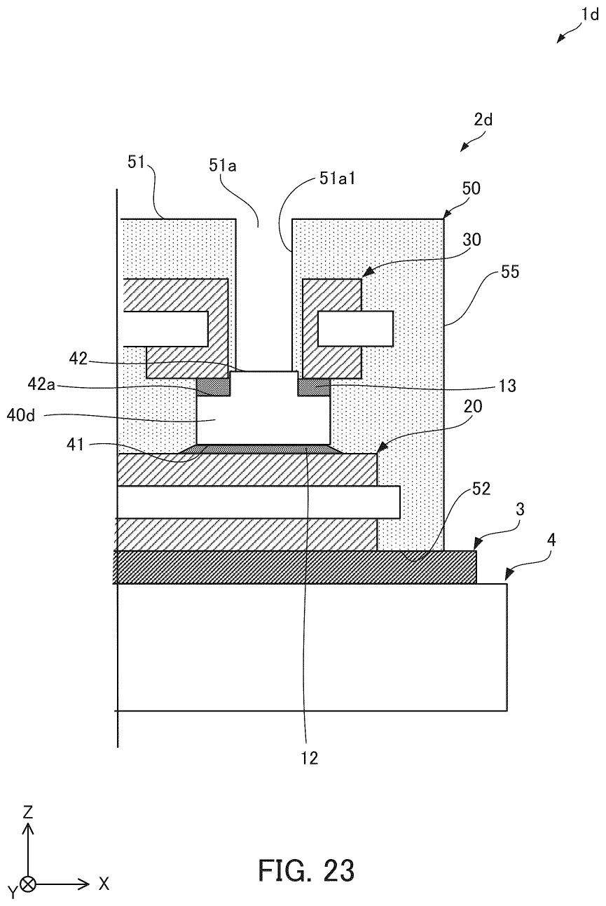

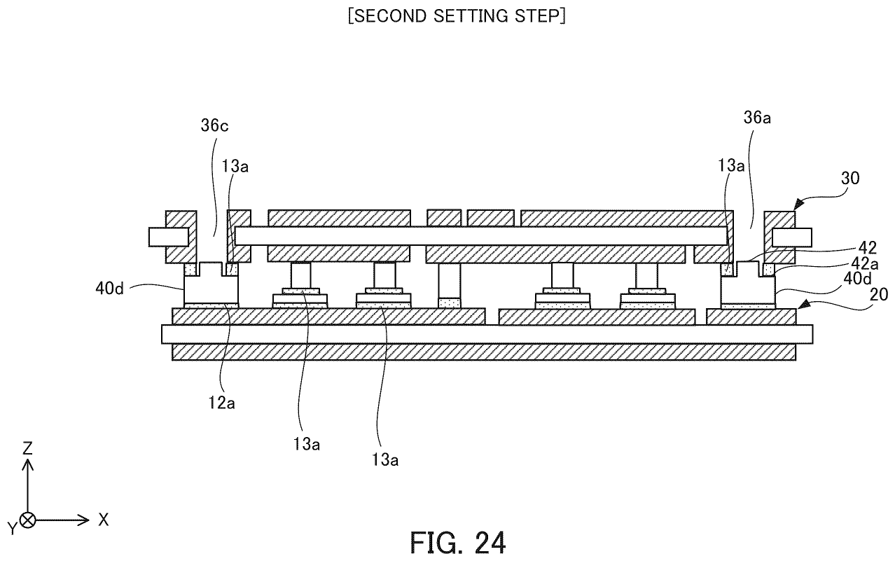

A semiconductor module 2d included in a semiconductor device 1d according to the fifth embodiment will now be described with reference to FIGS. 23 and 24. FIG. 23 is a cross-sectional view of (a main part of) the semiconductor device according to the fifth embodiment. FIG. 24 is a cross-sectional view useful in explaining a second setting step in a method of manufacturing the semiconductor module according to the fifth embodiment. Note that the description here will mainly focus on differences from the semiconductor module 2 of the first embodiment.

The semiconductor device 1d of the fifth embodiment includes the semiconductor module 2d and a cooling module 4 on which the semiconductor module 2d is disposed via a bonding member 3. The semiconductor module 2d includes semiconductor chips 10a and 10b, an insulated circuit board 20, a wiring board 30, conductive spacers 40d, and an encapsulating member 50 that encapsulates these components.

In the fifth embodiment, an entire range of an upper bonding surface 42 of each conductive spacer 40d aside from regions facing the opening edge portions of through-hole portions 36a, 36b, and 36c of the wiring board 30 protrudes upward. That is, as depicted in FIG. 23, a central region of the upper bonding surface 42 of the conductive spacer 40d that excludes the outer edge region protrudes toward the wiring board 30. With this configuration also, a step 42a that is continuous around the outer edge region of the upper bonding surface 42 of each conductive spacer 40d is formed.

By using these conductive spacers 40d, solder 13a is provided between the steps 42a in the conductive spacers 40d and the opening edge portions of the through-hole portions 36a, 36b, and 36c of the wiring board 30 immediately after the second setting step (step P3) of the method of manufacturing the semiconductor module 2d. When doing so, the solder 13a is located at a lower position than the central region of the conductive spacer 40d. Note that the through-hole portions 36a and 36c of the wiring board 30 are depicted in FIG. 24.

After this, in a solder bonding step (step P4), reflowing of the solder is performed to melt the solder 12a and the solder 13a. When doing so, the melted solder 13a is suppressed from spreading by the central regions of the conductive spacers 40d protruding upward from the upper bonding surfaces 42.

In the semiconductor module 2d manufactured by performing these steps, the solder 13 does not remain on the upper bonding surfaces 42 of the conductive spacers 40d exposed from openings 51a, 51b, and 51c. This makes it possible to reliably bond a bus bar 7 to the upper bonding surface 42 of the conductive spacer 40d through the openings 51a, 51b, and 51c.

According an aspect of the present disclosure, inductance is reduced while miniaturizing a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including an upper surface electrode and a lower surface electrode;
an insulated circuit board that includes a conductive circuit pattern layer on an upper surface thereof, the lower electrode surface of the semiconductor chip being disposed on the conductive circuit pattern layer;
a wiring board that includes a wiring pattern layer on a lower surface thereof, the wiring pattern layer being disposed to face the upper surface of the insulated circuit board, and being electrically connected to the upper surface electrode of the semiconductor chip;
a conductive spacer that is disposed between the conductive circuit pattern layer and the wiring pattern layer, the conductive spacer having:
a lower bonding surface bonded to the conductive circuit pattern layer, and
an upper bonding surface bonded to the wiring pattern layer,
to thereby conductively connect the conductive circuit pattern layer and the wiring pattern layer; and
an encapsulating member that encapsulates the semiconductor chip, the insulated circuit board, the wiring board and the conductive spacer while exposing the upper bonding surface of the conductive spacer and a lower surface of the insulated circuit board.

2. The semiconductor device according to claim 1, wherein:
the encapsulating member has an opening formed from an upper surface thereof, and
the upper bonding surface of the conductive spacer is exposed from the opening.

3. The semiconductor device according to claim 2, wherein:
the wiring board is formed with a through-hole portion that passes through the wiring board and corresponds to the opening in the encapsulating member, an inner surface of the through-hole portion being covered by the encapsulating member, and
the upper bonding surface of the conductive spacer is bonded via a solder to an opening edge portion of the through-hole portion.

4. The semiconductor device according to claim 3, wherein the upper bonding surface of the conductive spacer that is soldered to the opening edge portion of the through-hole portion has a region that is recessed downward therefrom.

5. The semiconductor device according to claim 3, wherein a central region of the upper bonding surface of the conductive spacer protrudes upward.

6. The semiconductor device according to claim 3, wherein:
the through-hole portion of the wiring board is formed by cutting out an edge portion of the wiring board, and
the opening in the encapsulating member is formed by cutting out an edge portion of the encapsulating member to expose the through-hole portion.

7. The semiconductor device according to claim 2, further comprising an external connection terminal bonded to the exposed upper bonding surface of the conductive spacer.

8. The semiconductor device according to claim 7, wherein the external connection terminal is bonded to the upper bonding surface of the conductive spacer by laser welding.

9. The semiconductor device according to claim 1, further comprising an external connection terminal bonded to the exposed upper bonding surface of the conductive spacer.

10. The semiconductor device according to claim 9, wherein the external connection terminal is bonded to the upper bonding surface of the conductive spacer by laser welding.
